(19) United States
(12) Patent Application Publication
(10) Pub. No.: US 2006/0273370 A1
(43) Pub. Date: Dec. 7, 2006

(54) NROM flash memory with vertical transistors and surrounding gates

(75) Inventor: Leonard Forbes, Corvallis, OR (US)

Correspondence Address: LEFFERT JAY & POLGLAZE, P.A.;Attn: Kenneth W. Bolvin, P.O. Box 581009, Minneapolis, MN, 55402, US

(73) Assignee: Micron Technology, Inc.

(21) Appl. No.: 11/146,679

(22) Filed: Jun. 7, 2005

(51) Int. Cl. H01L 29/94

(52) U.S. Cl. 257/302

(57) ABSTRACT

An NROM flash memory array is comprised of a plurality of surrounding gate NROM flash memory cells. The transistors are pillar-type devices with either silicon pillars or silicon bodies on oxide pillars. The array comprises a substrate with a plurality of the pillars organized in rows and columns. An upper diffusion region is implanted at the top of each pillar and a lower diffusion region implanted in the substrate between adjacent pillars. A gate insulator layer, comprising either a composite structure or a nanolaminate structure, is formed over the substrate and around each pillar. A surrounding gate is formed around each pillar. A word line is coupled to the surrounding gates of each row of transistors. A data/bit line couples the upper diffusion regions of each column of pillars.

### TECHNICAL FIELD OF THE INVENTION

The present invention relates generally to memory devices and in particular the present invention relates to nitride read only memory (NROM) flash memory device architecture.

### BACKGROUND OF THE INVENTION

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory. One type of flash memory is a nitride read only memory (NROM). NROM has some of the characteristics of flash memory but does not require the special fabrication processes of flash memory. NROM integrated circuits can be implemented using a standard CMOS process.

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, personal digital assistants (PDAs), digital cameras, and cellular telephones. Program code and system data such as a basic input/output system (BIOS) are typically stored in flash memory devices for use in personal computer systems.

The performance and density of flash memory transistors needs to increase as the performance of computer systems increases. To accomplish the density and performance increase, the transistors can be reduced in size. This has the effect of increased speed with decreased power requirements.

However, a problem with decreased flash memory size is that flash memory cell technologies have some scaling limitations. For example, stress induced leakage typically requires a tunnel oxide above 60 Å. This thickness results in a scaling limit on the gate length. Additionally, this gate oxide thickness limits the read current and may require large gate widths.

For the reasons stated above, and for other reasons stated below which will become apparent to those skilled in the art upon reading and understanding the present specification, there is a need in the art for a more scalable, higher performance, higher density flash memory transistor.

### SUMMARY

The above-mentioned problems with flash memory scaling and performance and other problems are addressed by the present invention and will be understood by reading and studying the following specification.

The present invention encompasses an NROM flash memory array. The array is comprised of a plurality of surrounding gate NROM flash memory cells. The array comprises a substrate with a plurality of vertical silicon pillars organized in rows and columns.

An upper diffusion region is implanted at the top of each silicon pillar and a lower diffusion region implanted at the bottom of each silicon pillar. A gate insulator layer, comprising either a composite structure or a nanolaminate structure, is formed over the substrate and around each silicon pillar.

A surrounding gate is formed around each silicon pillar to form a plurality of transistors with the silicon pillar. A word line is coupled to the surrounding gates of each row of transistors. A data/bit line couples the upper diffusion regions of each column of pillars.

In an alternate embodiment, the silicon pillars are replaced with oxide pillars with either ultra-thin silicon bodies grown or etched on the sides of each pillar. Silicon diffusion regions are formed on top and implanted in the substrate between adjacent oxide pillars in a column. A gate insulator layer, comprising either a composite structure or a nanolaminate structure, is formed over the substrate and around each oxide pillar. A surrounding gate is formed around the oxide pillars and over the ultra-thin silicon bodies. The rows of the array are coupled by a word/address line coupled to each surrounding gate in the row.

The gate insulator of each embodiment is comprised of a composite oxide—high-K dielectric—oxide/nitride composite structure, an oxide—nitride—high-K dielectric nanolaminate structure, a high-K—high-K—high-K dielectric nanolaminate structure, or a high-K—high-K—oxide nanolaminate structure.

Further embodiments of the invention include methods and apparatus of varying scope.

### BRIEF DESCRIPTION OF THE DRAWINGS

FIG. 1 shows a three-dimensional, a cross-sectional view of one embodiment of vertical transistors and surrounding gates of an NROM memory array of the present invention.

FIG. 2 shows a cross-sectional view along axis A-A′ of the NROM memory array of FIG. 1.

FIG. 3 shows a three-dimensional, a cross-sectional view of an alternate embodiment of vertical transistors with surrounding gates of an NROM memory array of the present invention.

FIG. 4 shows a cross-sectional view along axis A-A′ of the NROM memory array of FIG. 3.

FIG. 5 shows a cross-sectional view of another embodiment of vertical transistors and surrounding gates of NROM memory devices of the present invention.

FIG. 6 shows a cross-sectional view along axis B-B′ of the NROM memory devices of FIG. 5 with a ground plane.

FIG. 7 shows a cross-sectional view along axis B-B′ of the NROM memory devices of FIG. 5 with patterned, buried data/bit lines and a virtual ground array.

FIG. 8 shows one embodiment of a method for etching ultra-thin body silicon pillars with sub-lithographic sizes of the present invention.

FIG. 9 shows another embodiment of a method for etching the ultra-thin body silicon pillars with sub-lithographic sizes of the present invention.

FIG. 10 shows another view in accordance with the embodiment of FIG. 9.

FIG. 11 shows an electrical schematic diagram in accordance with the embodiment of FIG. 5 using a virtual ground array with two storage regions.

FIG. 12 shows one embodiment for a write operation of the present invention in accordance the embodiment of FIG. 1.

FIG. 13 shows one embodiment for a read operation of the present invention in accordance with the embodiment of FIG. 1.

FIG. 14 shows a block diagram of an electronic system of the present invention.

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof. The terms wafer or substrate used in the following description includes any base semiconductor structure. Both are to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a wafer or substrate in the following description, previous process steps may have been utilized to form regions/junctions in the base semiconductor structure, and terms wafer or substrate include the underlying layers containing such regions/junctions.

The NROM flash memory embodiments of the present invention are comprised of surrounding gate transistors and NROM devices that have composite oxide-nitride-oxide gate insulators. The embodiments of the flash memory devices also include high dielectric constant (high-K) dielectric composite gate insulators.

The following embodiments are described as NOR architecture memory arrays having a transistor at the intersection of an address and a data/bit line. However, the embodiments of the present invention are not limited to any one memory architecture.

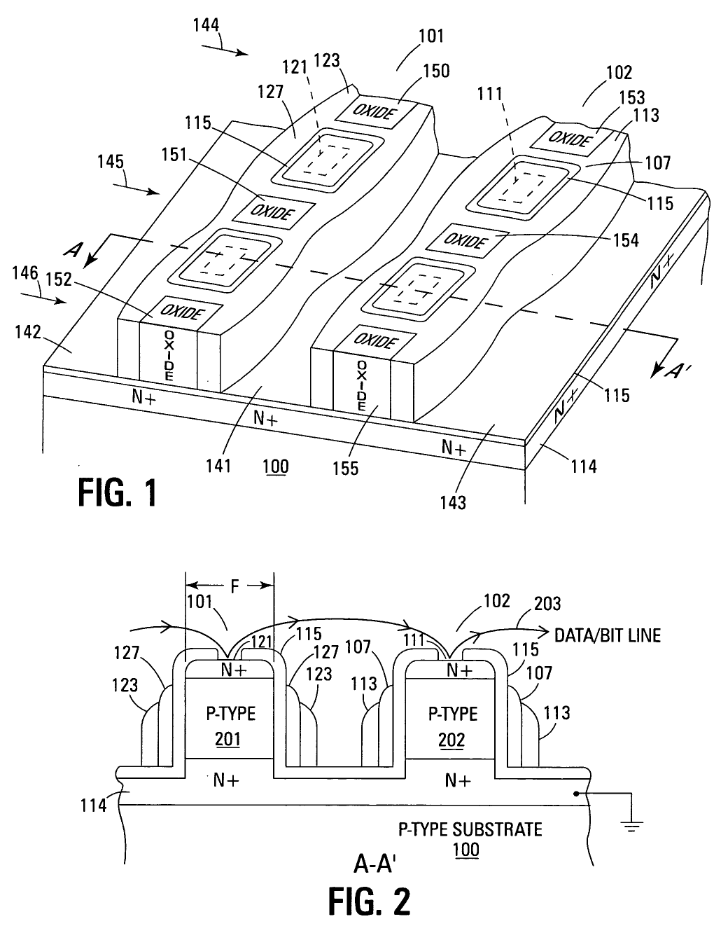

FIG. 1 illustrates a three-dimensional, a cross-sectional view of one embodiment of an NROM flash memory array of the present invention that is comprised of a vertical transistor with surrounding gate transistors for each flash memory device. In this embodiment, the vertical transistor is a silicon pillar transistor.

The NROM memory array of FIG. 1 is comprised of a p-type substrate 100 with a sheet n+ layer 114 that is formed into the surface of the wafer and annealed. This n+ layer 114 acts as the ground plane/source regions of the transistors that will be shown in greater detail subsequently with reference to FIG. 2. An alternate embodiment may use an n-type substrate with p-type diffusion regions for the source/drain regions.

Trenches 141-146 are etched in a silicon layer over the n+ implant layer 114. The trenches 141-146 are etched in both directions 141-143 and 144-146 to form the silicon pillars of the vertical transistors. The tops of the silicon pillars each have an implanted and annealed n+ region that, in one embodiment, acts as the drain region for the transistor. In an alternate embodiment, the top n+ region can be the source region, depending on the direction of operation of the transistor.

An insulator layer 115 is formed over the ground plane 114. In a prior art memory device, this insulator layer would be a gate oxide or gate insulator layer. The embodiments of the present invention use an oxide-nitride-oxide composite layer 115 or a high-K dielectric nanolaminate 115 to make the NROM device. For example, the high-K dielectric nanolaminates can include an oxide—high-K dielectric—oxide/nitride composite layer, an oxide—nitride—high-K dielectric composite layer, a high-K—high-K—high-K composite layer, or a high-K—high-K—oxide composite layer. Alternate embodiments may use other types of composite gate insulator layers 115.

The NROM transistor of the present invention uses the high-k dielectric layer as a trapping layer. In order to improve the programming speed and/or lower the programming voltage of an NROM device, it is desirable to use a trapping material with a lower conduction band edge (i.e., a higher electron affinity) to achieve a larger offset as well as to provide for programming by direct tunneling at low voltages.

The simplest nanolaminates with high-k dielectrics are oxide—high-k dielectric—oxide composites. Since silicon dioxide has a low electron affinity and high conduction band offset with respect to the conduction band of silicon, these nanolaminates have a high barrier, Φ, between the high-k dielectric and the oxide. Examples of oxide—high-k dielectric—oxide/nitride composites can include: oxide—ALD HfO₂—oxide, oxide—evaporated HfO₂—oxide, oxide—ALD ZrO₂—oxide, oxide—evaporated ZrO₂—oxide, oxide—ALD ZrSnTiO—oxide, oxide—ALD ZrON—oxide, oxide—evaporated ZrON—oxide, oxide—ALD ZrAlO—oxide, oxide—ALD ZrTiO₄—oxide, oxide—ALD Al₂O₃—oxide, oxide—ALD La₂O₃—oxide, oxide—LaAlO₃—oxide, oxide—evaporated LaAlO₃—oxide, oxide—ALD HfAlO₃—oxide, oxide—ALD HfSiON—oxide, oxide—evaporated Y₂O₃—oxide, oxide—evaporated Gd₂O—oxide, oxide—ALD Ta₂O₅—oxide, oxide—ALD TiO₂—oxide, oxide—evaporated TiO₂—oxide, oxide—ALD Pr₂O₃—oxide, oxide—evaporated Pr₂O₃—oxide, oxide—evaporated CrTiO₃—oxide, oxide—evaporated YSiO—oxide, oxide—Zr-doped Ta Oxide—oxide, oxide—ALD HfO₂—Si₃N₄, oxide—ALD TiAlOₓ—oxide, oxide—ALD LaAlO₃—oxide, oxide—ALD La₂Hf₂O₇—oxide, and oxide—ALD HfTaO—oxide.

The oxide—nitride—high-K dielectric composite insulator layer 115 avoids tunneling between the trapping centers in the nitride layer of a conventional NROM device and the control gate. High-k dielectrics, in one embodiment, can be used as the top layer in the gate insulator nanolaminate. Since they have a much higher dielectric constant than silicon oxide, these layers can be much thicker and still have the same capacitance. The thicker layers avoid tunneling to the control gate that is an exponential function of electric fields but have an equivalent oxide thickness that is much smaller than their physical thickness.

Examples of an oxide—nitride—high-K dielectric composite insulator layer 115 can include: oxide—nitride—ALD Al₂O₃, oxide—nitride—ALD HfO₂, and oxide—nitride—ALD ZrO₂.

The high-K—high-K—high-K composite insulator layer 115 has a larger energy depth with respect to the conduction band in the high-k trapping layer than the above composite insulators. As a result, large offsets are not required between the layers in the nanolaminates and a wide variety of different nanolaminates are possible using only high-k dielectrics in these nanolaminates. The energy depths of the traps can be adjusted by varying process conditions.

Examples of the high-K—high-K—high-K composite insulator layer 115 can include: ALD HfO₂—ALD Ta₂O₅—ALD HfO₂, ALD La₂O₃—ALD HfO₂—ALD La₂O₃, ALD HfO₂—ALD ZrO₂—ALD HfO₂, ALD Lanthanide (Pr, Ne, Sm, Gd, and Dy) Oxide—ALD ZrO₂—ALD Lanthanide (Pr, Ne, Sm, Gd, and Dy) Oxide, ALD Lanthanide Oxide—ALD HfO₂—ALD Lanthanide Oxide, and ALD Lanthanide Oxide—evaporated HfO₂—ALD Lanthanide Oxide.

Examples of the high-K—high-K—oxide composite insulator layer 115 can include: ALD TiO₂—ALD CeO₂—oxide, ALD of PrOx—ALD ZrO₂—oxide, and ALD CeO₂—ALD Al₂O₃—oxide.

In one embodiment, the high-k gate dielectric layer is fabricated using atomic layer deposition (ALD). As is well known in the art, ALD is based on the sequential deposition of individual monolayers or fractions of a monolayer in a well-controlled manner. In another embodiment of the NROM memory transistor of the present invention, the high-k dielectric layers can be fabricated using evaporation techniques that deposit thin films using thermal evaporation, electron beam evaporation, or some other form of evaporation.

The above-described examples for the composite gate insulator layer 115 are for illustration purposes only. Alternate embodiments can use other insulator compositions and/or methods of forming (e.g., chemical vapor deposition).

The composite gate insulator layer 115, in one embodiment, covers each silicon pillar except for a contact area 111, 121 on top of each pillar. As shown and discussed subsequently, this contact area 111, 121 enables contact with the silicon pillar's top n+ region (i.e., drain region) by the data/bit lines in order to form the columns of the memory array.

A surrounding polysilicon gate 107, 127 is formed around each silicon pillar and over the composite gate insulator layer 115. The surrounding gates 107, 127 provide improved transistor characteristics including improved control over the body of the transistor, improved leakage control, and improved short channel characteristics. The surrounding gate 107, 127 can be formed by polysilicon deposition and directional etch.

The structure is then completely filled with oxide and planarized by chemical mechanical polishing (CMP). This forms the oxide insulator pillars 150-155 between each of the silicon pillars. The oxide pillars 150-155 provide isolation between adjacent NROM devices. The trenches are opened and directionally etched between rows 101, 102.

A word line 113, 123 is formed around the surrounding gates 107, 127. The word lines 113, 123 coupled the surrounding gates 107, 127 together to form a row 101, 102 of the array. For purposes of clarity, the view of FIG. 1 shows only two rows 101, 102 in a memory array that is actually comprised of a large number of rows.

FIG. 2 illustrates a cross-sectional view along axis A-A′ of the embodiment of FIG. 1. This view shows the various elements of the surrounding gate transistors and NROM flash memory structures of the present invention. The transistors have minimum feature size, F, dimensions.

FIG. 2 shows the n+ ground plane 114 in the substrate 100. The composite gate insulator layer 115 is formed over each silicon pillar 201, 202 in each row 101, 102. In one embodiment, the oxide pillars 201, 202 are 100 nm or less. Alternate embodiments can use other pillar lengths. The n+ region formed at the top of each pillar 201, 202 has a contact area 121, 111 that is connected to a data/bit line 203. The data/bit line 203 couples each memory device in a NOR memory array column.

The surrounding gate structure 127, 107 is formed over the gate insulator 115. The word line structure 123, 113 is formed over the surrounding gate 127, 107.

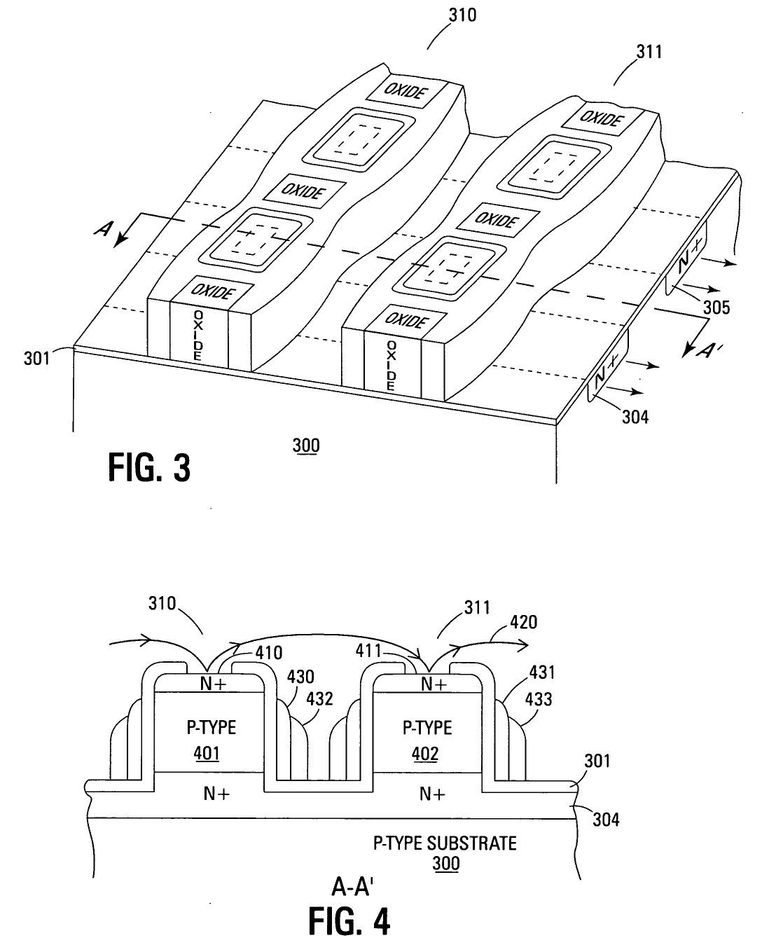

FIG. 3 illustrates a three-dimensional, a cross-sectional view of an alternate embodiment of vertical transistors with surrounding gates of an NROM memory array of the present invention. This embodiment is substantially similar to the embodiment of FIGS. 1 and 2 but employs patterned, buried data/bit lines. In one embodiment, the buried data/bit lines are comprised of a metal.

This embodiment is comprised of the substrate 300 over which the gate insulator layer 301 is formed. The gate insulator layer 301 of the embodiment of FIG. 3 is substantially the same as the insulator layer 115 of the embodiment of FIG. 1. This layer 301 was previously described in greater detail.

Two rows 310, 311 of the NROM memory array are illustrated. A cross-section along axis A-A′ of these rows and the substrate is illustrated in FIG. 4.

FIG. 4 illustrates a cross-sectional view of the embodiment of FIG. 4. A cross-section of one of the buried data/bit lines 304 is shown implanted in the substrate 300. A p-type substrate is illustrated with n+ buried data/bit lines. An alternate embodiment may have p-type buried data/bit lines in an n-type substrate.

An n+ region 410, 411 is also formed at the tops of each of the silicon pillars 401, 402. Each silicon pillar has a contact area on top of the n+ region 410, 411 to which a data/bit line 420 is coupled. In one embodiment, the silicon pillars 401, 402 are 100 nm or less in length. Alternate embodiments use other pillar lengths.

A surrounding gate 430, 431 is formed around each pillar 401, 402. The word line 432, 433 for each row 310, 311 is then formed around the surrounding gate 430, 431 in order to coupled the transistors to the other transistors in each row 310, 311.

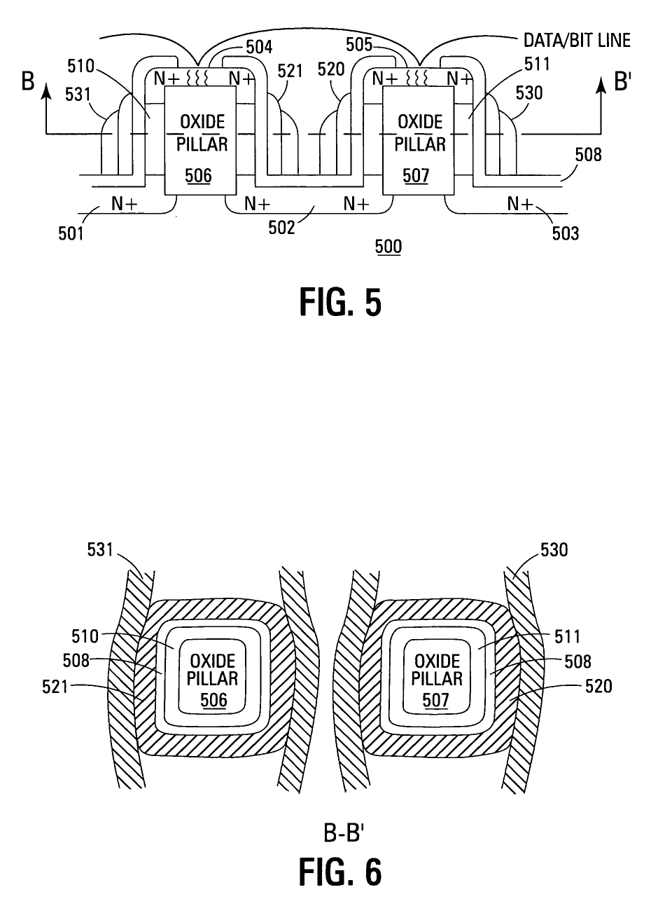

FIG. 5 illustrates a cross-sectional view of another embodiment of vertical transistors and surrounding gates of NROM memory devices of the present invention. This embodiment employs oxide pillars 506, 507 with ultra-thin silicon bodies grown along the sides of the pillars. In one embodiment, the oxide pillars 506, 507 are 100 nm or less in length. Alternate embodiments use other pillar lengths. The oxide pillars serve as an insulating carrier and also provide mechanical strength for the transistors.

The p-type substrate 500 has implanted and annealed n+ regions 501-503 that act as the source regions. These regions 501-503 are formed under the trenches between each pair of oxide pillars 506, 507.

Amorphous silicon is formed over the oxide pillars as n+ drain regions. The substrate 500 and active areas 501-505 of the present invention are not limited to any one conductivity type.

The ultra-thin bodies 510, 511 grown surrounding the oxide pillars 506, 507 are formed from single crystalline silicon that is re-crystallized along the sides of the pillars 506, 507 by solid phase epitaxial growth. Alternate embodiments may use other materials or means in the formation of the bodies 510, 511. The ultra-thin bodies 510, 511 are formed between the upper 504, 505 and lower 501-503 diffusion regions.

In the embodiment of FIG. 5, the ultra-thin silicon bodies 510, 511 are formed to a thickness of 10 nm (i.e., 100 Å). Alternate embodiments can form the bodies 510, 511 to a thickness in the range of 5-20 nm. Still other embodiments use other thicknesses.

Since the oxide pillars 506, 507 are relatively short and crystal growth can occur over short distances, the tops of the pillars can have grain boundaries in the polycrystalline silicon. However, these are of no consequence since the polycrystalline silicon is used as a contact area for the data/bit line connections. As is well known in the art, a grain boundary is the boundary between grains in polycrystalline material. It is a discontinuity of the material structure having an effect on its fundamental properties.

The composite gate insulator layer 508 is formed over the ultra-thin silicon bodies 510, 511, leaving the contact area open on the tops of the oxide pillars/n+ regions 504, 505. The gate insulator layer 508 of the embodiment of FIG. 5 is substantially the same as the composite or nanolaminate gate insulator layers of previous embodiments that were discussed above in detail.

The surrounding gates 520, 521 are formed around the oxide pillars as in previous embodiments. The surrounding gates 520, 521, in one embodiment, are polysilicon gates. Word lines 530, 531 are formed around the surrounding gates 520, 521. The word lines 530, 531 connect the rows of transistors as in the previous embodiments.

The memory devices of FIG. 5 can operate as single storage location devices with the charge storage region at the bottom of the pillar in the composite or nanolaminate gate insulator layer in a NOR type array with a ground plane. In a virtual ground array embodiment with patterned, buried data/bit lines, two storage regions can be used. Each storage region would be near each end of the channel.

FIG. 6 illustrates a cross-sectional view of the embodiment of FIG. 5 along the B-B′ axis. This embodiment uses a ground plane as the lower diffusion region of the transistors. In one embodiment, this is an n+ ground plane.

FIG. 6 shows the center oxide pillars 506, 507 that are surrounded by the silicon bodies 510, 511. The composite/nanolaminate gate insulator layer 508 surrounds the silicon bodies 510, 511 to act as the charge storage layer as in previous embodiments. The surrounding gate layer 520, 521 is formed around the gate insulator layer 508. The word line 530, 531 is then formed around the surrounding gate layer 520, 521.

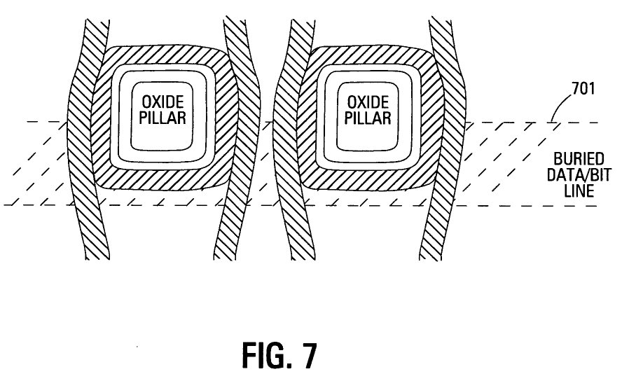

FIG. 7 illustrates a cross-sectional view of the embodiment of FIG. 5 along the B-B′ axis. This embodiment uses patterned, buried data/bit lines 701 as the lower diffusion regions of the transistors. In one embodiment, these are n+ buried data/bit lines. Except for the buried data/bit lines 701, the elements of this embodiment are substantially similar to the embodiment illustrated in FIG. 6 and will not be repeated.

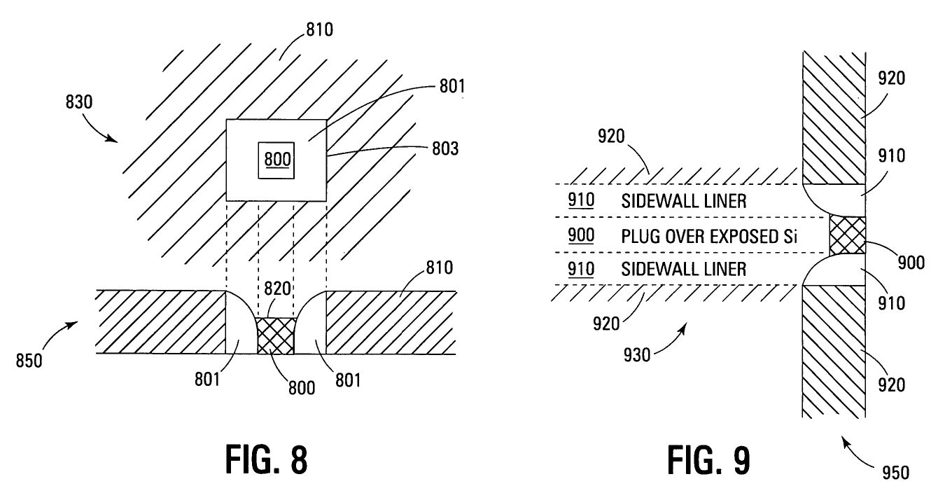

FIGS. 8-10 illustrate two embodiments for etching the ultra-thin body silicon pillars with sub-lithographic sizes or dimensions that are less than the minimum photolithography feature size. These embodiments are for purposes of illustration only since the present invention is not limited to any one fabrication technique.

FIG. 8 illustrates one embodiment for forming the ultra-thin body transistors with sub-lithographic dimensions by a sidewall spacer technique. The figure shows both the top view 830 and the side cross-sectional view.

A hole 803 is etched in a masking material 810 (e.g., silicon oxide) and silicon oxide is deposited and etched to leave on the sidewalls 801 of the hole. This produces a central region 800 with sub-lithographic dimensions. Silicon nitride can then be deposited, planarized, and etched to recess the nitride plug 820 in the hole 800. This plug 820 serves as the mask for the etch of the silicon pillars.

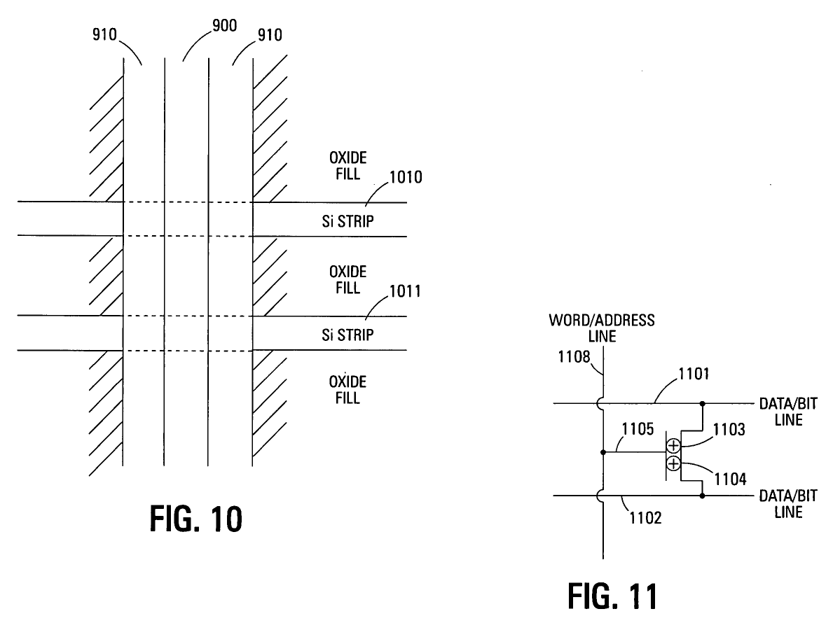

FIGS. 9-10 illustrate an alternate embodiment for forming the ultra-thin body transistors. FIG. 9 shows a top view 930 and a cross-sectional side view 950. FIG. 10 shows another top view that has been rotated.

In this embodiment, the trenches are etched in the mask material 920 in one direction and sidewall spaces 910 are formed along the side of the trenches. The empty strips are filled with nitride that is planarized and then recessed and the oxide removed. This leaves only the nitride plug 900 that can be used to etch strips of silicon. Ultra-thin strips of silicon (i.e., 1001, 1011 of FIG. 10) can then be etched in the other direction using the same technique. This leaves ultra-thin silicon pillars.

FIG. 11 illustrates an electrical schematic diagram in accordance with the embodiment of FIG. 5 using a virtual ground array. This diagram shows that the two buried data/bit lines 1101, 1102 are connected to the source and drain of the transistor. The function of a particular diffusion region (i.e., source or drain) is determined by the direction of operation of the transistor. The surrounding control gate of the transistor is connected to the word/address line 1108 that is the row of the memory array.

In one direction of operation, a first charge storage region 1103 (i.e., bottom or top of the channel) is used to store data. In a second direction of operation, a second charge storage region 1104 is used to store another bit of data.

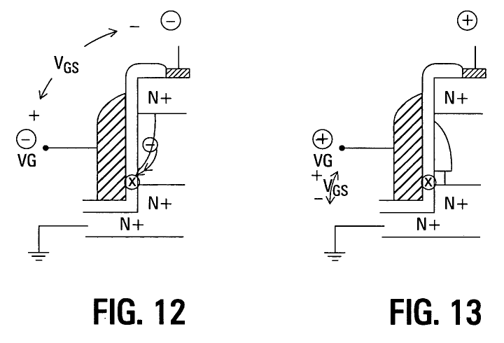

FIG. 12 illustrates one embodiment for a write operation of the present invention in accordance with the array ground plane embodiment of FIG. 1. To write data, the transistor is operated in the reverse direction with negative potentials on the drain and gate. The gate to source voltage, V_{GS}, is still positive. The transistor turns on and conducts such that hot electrons are injected into the composite/nanolaminate gate insulator near the bottom of the channel.

FIG. 13 illustrates one embodiment for a read operation of the present invention in accordance with the array ground plane embodiment of FIG. 1. To read the data, the transistor is operated in the normal forward direction (i.e., a positive voltage on drain and gate) and the conductivity of the channel is determined. If a charge is stored near the source, the conductivity of the channel will be lower and the presence of stored data is determined.

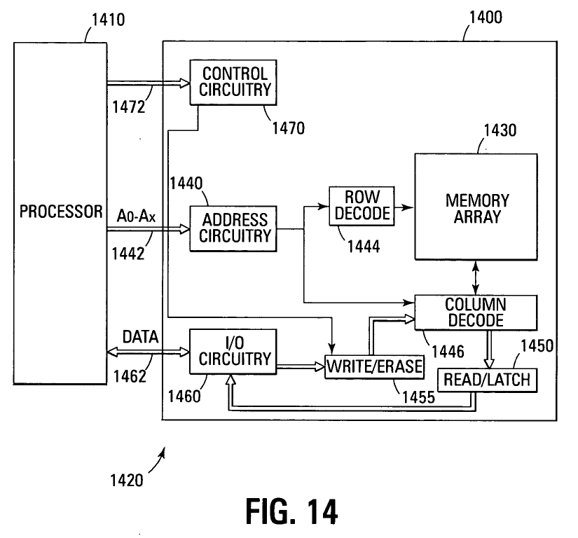

FIG. 14 illustrates a functional block diagram of a memory device 1400 that can incorporate the NROM array with vertical transistors and surrounding gates of the present invention. The memory device 1400 is coupled to a processor 1410. The processor 1410 may be a microprocessor or some other type of controlling circuitry. The memory device 1400 and the processor 1410 form part of an electronic system 1420. The memory device 1400 has been simplified to focus on features of the memory that are helpful in understanding the present invention.

The memory device includes an array of flash memory cells 1430 that can be NROM flash memory cells. The memory array 1430 is arranged in banks of rows and columns. The control gates of each row of memory cells is coupled with a word line while the drain and source connections of the memory cells are coupled to bit lines. As is well known in the art, the connection of the cells to the bit lines depends on whether the array is a NAND architecture, a NOR architecture, or some other architecture.

An address buffer circuit 1440 is provided to latch address signals provided on address input connections A0-Ax 1442. Address signals are received and decoded by a row decoder 1444 and a column decoder 1446 to access the memory array 1430. It will be appreciated by those skilled in the art, with the benefit of the present description, that the number of address input connections depends on the density and architecture of the memory array 1430. That is, the number of addresses increases with both increased memory cell counts and increased bank and block counts.

The memory device 1400 reads data in the memory array 1430 by sensing voltage or current changes in the memory array columns using sense amplifiers/buffer circuitry 1450. The sense/buffer circuitry, in one embodiment, is coupled to read and latch a row of data from the memory array 1430. Data input and output buffer circuitry 1460 is included for bidirectional data communication over a plurality of data connections 1462 with the controller 1410. Write circuitry 1455 is provided to write data to the memory array.

Control circuitry 1470 decodes signals provided on control connections 1472 from the processor 1410. These signals are used to control the operations on the memory array 1430, including data read, data write, and erase operations. The control circuitry 1470 may be a state machine, a sequencer, or some other type of controller.

Since the NROM memory cells of the present invention can use a CMOS compatible process, the memory device 1400 of FIG. 14 may be an embedded device with a CMOS processor.

The flash memory device illustrated in FIG. 14 has been simplified to facilitate a basic understanding of the features of the memory. A more detailed understanding of internal circuitry and functions of flash memories are known to those skilled in the art.

### Conclusion

In summary, the NROM flash memory array of the present invention is comprised of surrounding gate transistors that use composite or high-K nanolaminate gate insulator layers. The transistors are vertical devices based on silicon pillars, ultra-thin silicon bodies grown on oxide pillars, or ultra-thin etched bodies.

The NROM flash memory cells of the present invention may be NAND-type cells, NOR-type cells, or any other type of array architecture.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A surrounding gate NROM flash memory device comprising:
a substrate comprising a vertical silicon pillar;
an upper diffusion region at the top of the silicon pillar and a lower diffusion region at the bottom of the silicon pillar;
a gate insulator layer, comprising either a composite structure or a nanolaminate structure, formed over the substrate and around the silicon pillar;
a surrounding gate that is formed around the silicon pillar; and
a word line coupled to the surrounding gate.

2. The device of claim 1 wherein the diffusion regions are doped to be n+regions and the substrate is a p-type silicon.

3. The device of claim 1 wherein the lower diffusion region is coupled to other lower diffusion regions of adjacent devices in an NROM flash memory array to form a ground plane.

4. The device of claim 1 wherein the lower diffusion region is coupled to other lower diffusion regions of column adjacent devices in an NROM flash memory array to form a buried data/bit line that couples together a column of devices.

5. The device of claim 1 wherein the gate insulator layer has a composite structure of one of the following: oxide—HfO₂—oxide, oxide—ZrO₂—oxide, oxide—ZrSnTiO—oxide, oxide—ZrON—oxide, oxide—ZrAlO—oxide, oxide—ZrTiO₄—oxide, oxide—Al₂O₃—oxide, oxide—La₂O₃—oxide, oxide—LaAlO₃—oxide, oxide—HfAlO₃—oxide, oxide—HfSiON—oxide, oxide—Y₂O₃—oxide, oxide—Gd₂O—oxide, oxide—Ta₂O₅—oxide, oxide—TiO₂—oxide, oxide —Pr₂O₃—oxide, oxide—CrTiO₃—oxide, oxide —YSiO—oxide, oxide—Zr-doped Ta Oxide—oxide, oxide—HfO₂—SiN₄, oxide—TiAlOₓ—oxide, oxide—LaAlO₃—oxide, oxide—La₂Hf₂O₇—oxide, or oxide—HfTaO—oxide.

6. The device of claim 5 wherein the HfO₂, ZrO₂, ZrSnTiO, ZRON, ZrAlO, ZrTiO₄, Al₂O₃, La₂O₃, LaAlO₃, HfAlO₃, HfSiON, Ta₂O₅, TiO₂, Pr₂O₃, HfO₂, TiAlOₓ, LaAlO₃, La₂Hf₂O₇, HfTaO are formed by atomic layer deposition (ALD).

7. The device of claim 5 wherein the HfO₂, ZrO₂, ZrON, LaAlO₃, Y₂O₃, Gd₂O, TiO₂, Pr₂O₃, CrTiO₃, and YSiO are formed by evaporation.

8. The device of claim 7 wherein the evaporation is accomplished by either thermal evaporation or electron gun evaporation.

9. The device of claim 1 wherein the surrounding gate is formed from polysilicon.

10. The device of claim 1 wherein the gate insulator layer is comprised of a nanolaminate structure of one of the following: oxide—nitride—Al₂O₃, oxide—nitride—HfO₂, or oxide—nitride—ZrO₂.

11. The device of claim 10 wherein the Al₂O₃, HfO₂, and ZrO₂ are formed by atomic layer deposition.

12. An NROM flash memory array comprising:
a substrate comprising a plurality of vertical silicon pillars, each pillar having an upper diffusion region at the top of each pillar and a lower diffusion region at the bottom of each pillar;
a ground plane implanted in the substrate and coupled to the lower diffusion regions;
a gate insulator layer, comprising either a composite structure or a nanolaminate structure, formed over the ground plane and over each silicon pillar;
a surrounding gate that is formed around each silicon pillar; and
a plurality of word lines, each wordline coupled to the surrounding gates of a different row of silicon pillars.

13. The array of claim 12 wherein the gate insulator layer is formed over each silicon pillar such that a contact area to the upper diffusion region is left open and a data/bit line is coupled to the contact area of each pillar in a column of pillars.

14. The array of claim 12 wherein the gate insulator layer is comprised of one of the following high-K nanolaminate structures: HfO₂—Ta₂O₅—HfO₂, La₂O₃—HfO₂—La₂O₃, HfO₂—ZrO₂—HfO₂, Lanthanide (Pr, Ne, Sm, Gd, and Dy) Oxide—ZrO₂—Lanthanide Oxide, Lanthanide Oxide—HfO₂—Lanthanide Oxide, Lanthanide Oxide—HfO₂—Lanthanide Oxide, TiO₂—CeO₂—oxide, PrOₓ—ZrO₂—oxide, or CeO₂—Al₂O₃—oxide.

15. An NROM flash memory array comprising:
a substrate comprising a plurality of vertical silicon pillars organized in rows and columns, each pillar having an upper diffusion region at the top of each pillar and a lower diffusion region at the bottom of each pillar;
a plurality of buried data/bit lines each implanted along a column in the substrate, each data/bit line coupled to a different column of lower diffusion regions;
a gate insulator layer, comprising either a composite structure or a nanolaminate structure, formed over the substrate and over each silicon pillar;
a surrounding gate that is formed around each silicon pillar; and
a plurality of word lines, each wordline coupled to the surrounding gates of a different row of silicon pillars.

16. A surrounding gate NROM flash memory array comprising:
a substrate having a plurality of vertical oxide pillars, the pillars arranged in rows and columns, the columns being coupled by lower diffusion regions implanted in the substrate between pairs of adjacent oxide pillars;
an upper diffusion region formed on top of each oxide pillar;
a silicon body formed around each oxide pillar between the upper and lower diffusion regions;
a gate insulator layer, comprising either a composite structure or a nanolaminate structure, formed over the substrate and around each oxide pillar;
a surrounding gate formed around each oxide pillar to form at least two vertical transistors; and
a plurality of word lines each coupling the surrounding gates of a different row.

17. The array of claim 16 wherein the silicon body is formed to a thickness in a range of 5-20 nm.

18. The array of claim 16 wherein the lower diffusion regions of each column are coupled to a different buried data/bit line.

19. The array of claim 16 wherein adjacent upper diffusion regions in a column are coupled together by a data/bit line.

20. The array of claim 16 wherein the lower diffusion regions are coupled to a ground plane.

21. The array of claim 16 wherein the gate insulator layer can store two charges in each of the at least two transistors in response to a direction of operation of the transistors.

22. An electronic system comprising:
a processor that generates control signals; and
an NROM flash memory array coupled to the processor, the array comprising a plurality of surrounding gate NROM flash memory cells, each cell comprising:
a substrate comprising a vertical silicon pillar;
an upper diffusion region at the top of the silicon pillar and a lower diffusion region at the bottom of the silicon pillar;
a gate insulator layer, comprising either a composite structure or a nanolaminate structure, formed over the substrate and around the silicon pillar;
a surrounding gate that is formed around the silicon pillar; and
a word line coupled to the surrounding gate.

23. A method for fabricating a surrounding gate NROM flash memory device, the method comprising:
forming a vertical silicon pillar in a substrate;
implanting an upper diffusion region at the top of the silicon pillar and a lower diffusion region at the bottom of the silicon pillar;
forming a gate insulator layer, comprising either a composite structure or a nanolaminate structure, over the substrate and around the silicon pillar;
forming a surrounding gate around the silicon pillar; and
forming a word line that couples the surrounding gate of the NROM flash memory device to adjacent NROM flash memory devices in a row.

24. The method of claim 23 and further comprising coupling a data/bit line to the top of the silicon pillar in order to couple adjacent NROM flash memory devices in a column.

25. The method of claim 23 wherein the gate insulator layer is comprised of a high-k dielectric—high-k dielectric—high-k dielectric structure.

26. The method of claim 23 wherein forming the gate insulator layer comprises one of the following structures: oxide—HfO₂—oxide, oxide—HfO₂—oxide, oxide—ZrO₂—oxide, oxide—ZrO₂—oxide, oxide—ZrSnTiO—oxide, oxide—ZrON—oxide, oxide—ZrON—oxide, oxide—ZrAlO—oxide, oxide—ZrTiO₄—oxide, oxide—Al₂O₃—oxide, oxide—La₂O₃—oxide, oxide—LaAlO₃—oxide, oxide—evaporated LaAlO₃—oxide, oxide—HfAlO₃—oxide, oxide—HfSiON—oxide, oxide—Y₂O₃—oxide, oxide—Gd₂O —oxide, oxide—Ta₂O₅—oxide, oxide—TiO₂—oxide, oxide—TiO₂—oxide, oxide—Pr₂O₃—oxide, oxide—Pr₂O₃—oxide, oxide—CrTiO₃—oxide, oxide—YSiO—oxide, oxide—Zr-doped Ta Oxide—oxide, oxide—HfO₂—SiN₄, oxide—TiAlOₓ—oxide, oxide—LaAlO₃—oxide, oxide—La₂Hf₂O₇—oxide, or oxide—HfTaO—oxide.

27. The method of claim 23 wherein forming the gate insulator layer comprises forming one of the following structures: oxide—nitride—Al₂O₃, oxide—nitride—HfO₂, or oxide—nitride—ZrO₂

28. The method of claim 23 wherein forming the gate dielectric layer comprises forming one of the following structures: HfO₂—Ta₂O₅—HfO₂, La₂O₃—HfO₂—La₂O₃, HfO₂—ZrO₂—HfO₂, Lanthanide (Pr, Ne, Sm, Gd, and Dy) Oxide—ZrO₂—Lanthanide Oxide, Lanthanide Oxide—HfO₂—Lanthanide Oxide, or Lanthanide Oxide—HfO₂—Lanthanide Oxide.

29. The method of claim 23 wherein forming the gate insulator layer comprises an atomic layer deposition technique.

30. The method of claim 23 wherein forming the gate insulator layer comprises an evaporation technique.

31. The method of claim 23 wherein forming the gate insulator layer comprises an atomic layer deposition technique and an evaporation technique.

32. The method of claim 26 wherein forming the gate dielectric layer comprises evaporating one of the following materials: HfO₂, ZrO₂, ZrON, LaAlO₃, Y₂O₃, Gd₂O, TiO₂, CrTiO₃, or YSiO.

33. The method of claim 26 wherein forming the gate insulator layer comprises atomic layer deposition of one of the following materials: HfO₂, ZrO₂, ZrSnTiO, ZrON, ZrAlO, ZrTiO₄, Al₂O₃, La₂O₃, LaAlO₃, HfAlO₃, HfSiON, Ta₂O₅, TiO₂, or Pr₂O₃.

34. The method of claim 27 wherein forming the gate insulator layer comprises atomic layer deposition of one of the following materials: Al₂O₃, HfO₂, or ZrO₂.

35. The method of claim 23 wherein forming the gate insulator layer comprises depositing one of the following nanolaminate structures: HfO₂—Ta₂O₅—HfO₂, La₂O₃—HfO₂—La₂O₃, HfO₂—ZrO₂—HfO₂, Lanthanide (Pr, Ne, Sm, Gd, and Dy) Oxide—ZrO₂—Lanthanide Oxide, Lanthanide Oxide—HfO₂—Lanthanide Oxide, or Lanthanide Oxide—HfO₂—Lanthanide Oxide.

36. A method for fabricating a surrounding gate NROM flash memory array, the method comprising:
forming a plurality of vertical oxide pillars on a substrate, the pillars arranged in rows and columns, the columns being coupled by lower diffusion regions implanted in the substrate between pairs of adjacent oxide pillars;
forming an upper diffusion region on top of each oxide pillar;
forming a silicon body around each oxide pillar between the upper and lower diffusion regions;
forming a gate insulator layer, comprising either a composite structure or a nanolaminate structure, over the substrate and around each oxide pillar;
forming a surrounding gate around each oxide pillar to create at least two vertical transistors on each pillar; and
forming a plurality of word lines each coupling the surrounding gates of a different row.

37. The method of claim 36 wherein forming the silicon body comprises growing silicon on the oxide pillars.

38. The method of claim 36 wherein forming the silicon body comprises etching the silicon body around each oxide pillar.

39. A surrounding gate NROM flash memory array comprising:
a substrate comprising a plurality of pillars arranged in rows and columns;
an upper diffusion region at the top of each pillar and a lower diffusion region implanted in the substrate between adjacent pillars;
a gate insulator layer, comprising either a composite structure or a nanolaminate structure, formed over the substrate and around each pillar;
a surrounding gate that is formed around each pillar; and
a word line coupled to the surrounding gate.

40. The array of claim 39 wherein the pillars are silicon pillars.

41. The array of claim 39 wherein the pillars are oxide pillars surrounded by a silicon body.

42. The array of claim 39 wherein the lower diffusion regions are coupled to a ground plane.

43. The array of claim 39 wherein the lower diffusion regions are coupled to buried data/bit line that couple the lower diffusion regions of each column and the upper diffusion regions of each column are coupled with an upper data/bit line.
